(19) United States
(12) Patent Application Publication
(10) Pub. No.: US 2022/0342440 A1
(43) Pub. Date: Oct. 27, 2022

(54) SEMICONDUCTOR DEVICE AND CLOCK CONTROL METHOD

(71) Applicant: FUJITSU LIMITED, Kawasaki-shi (JP)

(72) Inventor: SHINICHIRO SHIROTA, Kawasaki (JP)

(73) Assignee: FUJITSU LIMITED, Kawasaki-shi (JP)

(21) Appl. No.: 17/672,746

(22) Filed: Feb. 16, 2022

(30) Foreign Application Priority Data
Apr. 26, 2021 (JP) 2021-073744

(51) Int. Cl. G06F 1/08; G01R 31/317; G06F 1/28; G06F 11/30

(52) U.S. Cl. CPC G06F 1/08; G01R 31/31727; G06F 1/28; G06F 11/3024

(57) ABSTRACT

A semiconductor device includes a clock circuit that outputs a clock signal of a first frequency, a detection circuit that detects occurrence of power supply noise and end of the power supply noise, and a control circuit. The control circuit drops, in a case where the occurrence of the power supply noise is detected, a frequency of the clock signal from the first frequency to a second frequency, determine a frequency return time according to a noise occurrence time from the occurrence of the power supply noise to the end of the power supply noise, and returns the frequency of the clock signal from the second frequency to the first frequency on the basis of the frequency return time.

### CROSS-REFERENCE TO RELATED APPLICATION

This application is based upon and claims the benefit of priority of the prior Japanese Patent Application No. 2021-73744, filed on Apr. 26, 2021, the entire contents of which are incorporated herein by reference.

### FIELD

The embodiment discussed herein is related to a clock control technology in a semiconductor device.

### BACKGROUND

Due to an increase in current consumption in large scale integration (LSI) such as a processor, a current change in a case where an operation load fluctuates also increases, and as a result, very large power supply noise may occur. When a power supply voltage drops due to the power supply noise, a delay time of an internal circuit of the LSI increases. The LSI is an example of a semiconductor device.

FIG. 1 illustrates an example of the LSI. The LSI of FIG. 1 includes a clock driver 101, a flip-flop (FF) 102, a logic circuit 103, and an FF 104. The clock driver 101 supplies a clock signal to the FF 102 and the FF 104, and the FF 102 outputs a data signal to the logic circuit 103 according to the clock signal.

The logic circuit 103 performs a logical operation by using the data signal output from the FF 102, and outputs a data signal of an operation result to the FF 104. A delay time of the data signal input to the FF 104 is the sum of a delay time Td at a normal power supply voltage and a delay time ΔTd increased by a drop of the power supply voltage.

FIG. 2 illustrates an example of the clock signal and the data signal in the LSI of FIG. 1. The clock signal represents the clock signal output from the clock driver 101, and a clock cycle represents a cycle of the clock signal. Output data represents the data signal output from the FF 102, and input data represents the data signal input to the FF 104.

In LSI design, a margin is added to the clock cycle so that the increased delay time ΔTd meets a timing constraint. In this example, ΔTd is added as the margin of the clock cycle so that Td+ΔTd falls within the clock cycle.

In a case where power supply noise is large, the margin of the clock cycle is also increased. When the margin of the clock cycle in a processor increases, a frequency of the clock signal drops, which hinders improvement of an operation speed and a decrease in power consumption of the processor. Therefore, in recent processors, a technology for avoiding a timing error by adopting a small value as a margin of a clock cycle and dropping a frequency of a clock signal in a case where occurrence of power supply noise is detected may be applied.

In relation to control of a clock signal associated with power supply noise, a control program for suppressing occurrence of a timing error due to power supply noise without increasing frequency at which a clock frequency drops is known. An electronic circuit capable of changing an oscillation frequency at high-speed following power supply noise is also known. A semiconductor device capable of following a fast voltage change such as a large voltage drop occurring at the time of rapid load fluctuation is also known.

Japanese Laid-open Patent Publication No. 2020-98545, Japanese Laid-open Patent Publication No. 2017-17671, and Japanese Laid-open Patent Publication No. 2017-58911 are disclosed as related art.

### SUMMARY

According to an aspect of the embodiments, a semiconductor device including: a clock circuit that outputs a clock signal of a first frequency; a detection circuit that detects occurrence of power supply noise and end of the power supply noise; and a control circuit that drops, in a case where the occurrence of the power supply noise is detected, a frequency of the clock signal from the first frequency to a second frequency, determine a frequency return time according to a noise occurrence time from the occurrence of the power supply noise to the end of the power supply noise, and returns the frequency of the clock signal from the second frequency to the first frequency on the basis of the frequency return time.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF DRAWINGS

FIG. 1 is a diagram illustrating large scale integration (LSI);

FIG. 2 is a diagram illustrating a clock signal and a data signal in the LSI;

FIG. 3 is a timing chart of clock control in a comparative example;

FIGS. 4A and 4B are configuration diagrams of a circuit that performs the clock control in the comparative example;

FIG. 5 is a timing chart of the clock control when the maximum power supply noise occurs in the comparative example;

FIG. 6 is a timing chart of the clock control when short-period small noise occurs in the comparative example;

FIG. 7 is a configuration diagram of a semiconductor device of an embodiment;

FIG. 8 is a flowchart of clock control;

FIG. 9 is a first hardware configuration diagram of LSI;

FIG. 10 is a first hardware configuration diagram of a clock control circuit;

FIG. 11 is a diagram illustrating a candidate time table;

FIG. 12 is a timing chart of the clock control when short-period small noise occurs in the LSI;

FIGS. 13A to 13C are diagrams illustrating first clock control;

FIG. 14 is a flowchart of the first clock control;

FIG. 15 is a second hardware configuration diagram of the clock control circuit;

FIG. 16 is a diagram illustrating second clock control;

FIG. 17 is a flowchart of the second clock control; and

FIG. 18 is a second hardware configuration diagram of the LSI.

### DESCRIPTION OF EMBODIMENTS

In a case where a frequency of a clock signal is dropped when power supply noise occurs, performance of a processor is deteriorated while operating with the low frequency clock signal.

Note that such a problem occurs not only in a processor but also in various semiconductor devices that operate according to a clock signal.

In one aspect, an embodiment aims to shorten a time for a semiconductor device to operate at a low frequency.

Hereinafter, an embodiment will be described in detail with reference to the drawings.

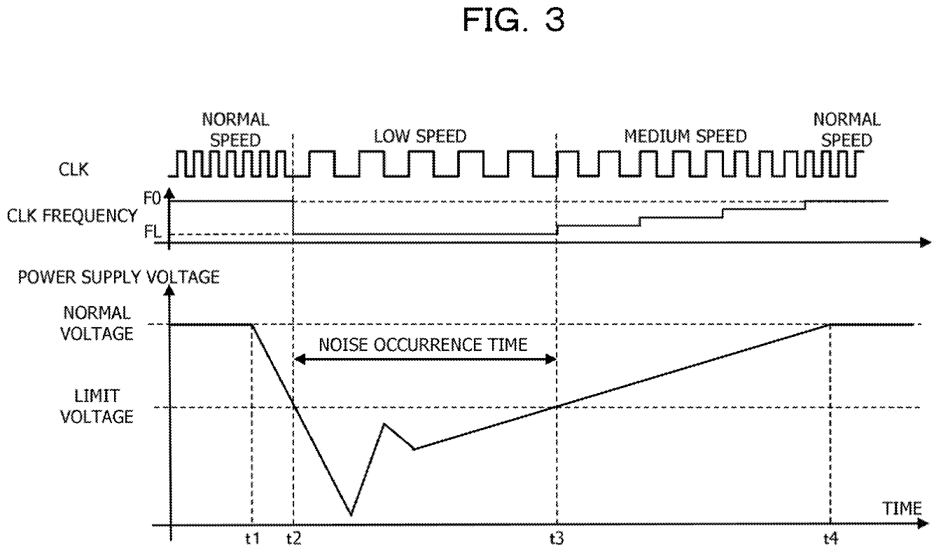

FIG. 3 is a timing chart illustrating an example of clock control in which a frequency of a clock signal is dropped when occurrence of power supply noise is detected in a processor of a comparative example. CLK represents the clock signal, and a CLK frequency represents the frequency of the clock signal. A normal speed corresponds to a frequency F0 of the clock signal in a normal operation of large-scale integration (LSI), a low speed corresponds to a frequency FL lower than the frequency of the normal speed, and the medium speed corresponds to a frequency between the frequency of the normal speed and the frequency of the low speed.

A normal voltage represents a power supply voltage in a normal operation of the processor, and a limit voltage represents a lower limit of a power supply voltage at which the processor may operate at the CLK frequency of the normal speed. When the power supply voltage drops below the limit voltage, the processor has difficulty in operating at the frequency F0.

At a start of operation, the CLK frequency is F0 and the processor is operating at the normal speed. At time t1, power supply noise occurs, and at time t2, the power supply voltage drops to the limit voltage. Thus, control is performed to change the CLK frequency to FL, and the processor operates at the low speed. As a result, a timing margin of the clock signal is increased, so that a timing error does not occur.

Thereafter, after the power supply voltage further drops, the power supply voltage starts to rise due to reduction of the power supply noise. Then, at time t3, the power supply noise ends, and the power supply voltage reaches the limit voltage. Thus, control is performed to gradually raise the CLK frequency, and the processor operates at the medium speed. The end of the power supply noise means that the power supply noise disappears. A noise occurrence time, which is a time from the occurrence to the end of the power supply noise, is a time from the time t2 to the time t3.

In the operation at the medium speed, the CLK frequency gradually rises from FL, and finally returns to F0. Then, the processor operates at the normal speed again. At time t4, the power supply voltage reaches the normal voltage.

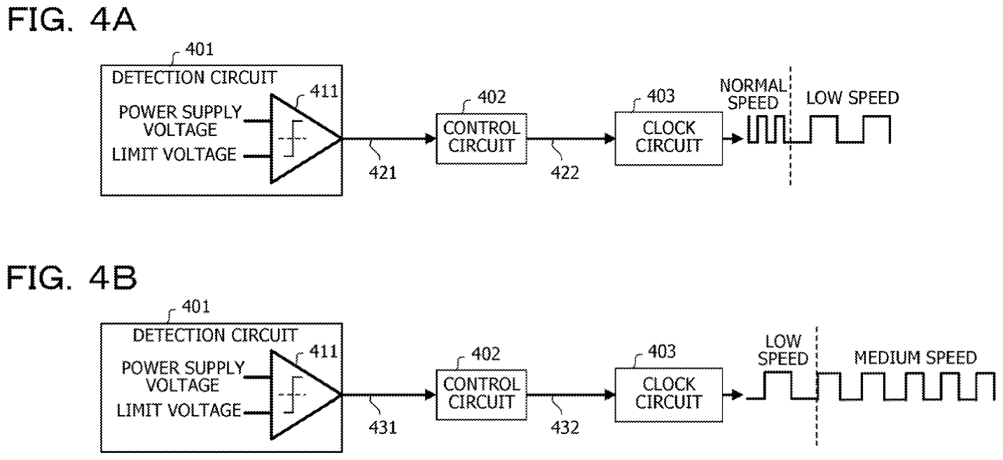

FIGS. 4A and 4B illustrate configuration examples of a circuit that performs the clock control of FIG. 3 in the processor of the comparative example. The circuit of FIGS. 4A and 4B includes a detection circuit 401, a control circuit 402, and a clock circuit 403. The detection circuit 401 includes a comparison circuit 411, and detects the occurrence and the end of the power supply noise. The clock circuit 403 may dynamically change the frequency of the clock signal.

FIG. 4A illustrates an example of the control for changing the CLK frequency to FL at the time t2. The comparison circuit 411 compares the power supply voltage and the limit voltage of the processor, and in a case where the power supply voltage drops below the limit voltage, outputs a noise occurrence signal 421 indicating the occurrence of the power supply noise to the control circuit 402.

When receiving the noise occurrence signal 421, the control circuit 402 outputs a frequency drop signal 422 indicating an instruction to change the CLK frequency to FL to the clock circuit 403. When receiving the frequency drop signal 422, the clock circuit 403 changes the CLK frequency to FL, and outputs the clock signal. As a result, the operation speed of the processor changes from the normal speed to the low speed.

FIG. 4B illustrates an example of the control for gradually raising the CLK frequency at the time t3. The comparison circuit 411 compares the power supply voltage and the limit voltage of the processor, and in a case where the power supply voltage reaches the limit voltage, outputs a noise end signal 431 indicating the end of the power supply noise to the control circuit 402.

When receiving the noise end signal 431, the control circuit 402 starts frequency return control for gradually raising the CLK frequency from FL to F0. In the frequency return control, the control circuit 402 outputs a frequency rise signal 432 indicating an instruction to raise the CLK frequency by a predetermined value to the clock circuit 403 at predetermined time intervals.

Each time the clock circuit 403 receives the frequency rise signal 432, the clock circuit 403 raises the CLK frequency by the predetermined value, and outputs the clock signal. As a result, the operation speed of the processor changes from the low speed to the medium speed. When the frequency rise signal 432 is received a predetermined number of times, the CLK frequency returns to F0, and the operation speed of the processor changes from the medium speed to the normal speed.

A rapid rise in the CLK frequency may be accompanied by large current fluctuation and may cause occurrence of the power supply noise again. In this case, the occurred power supply noise is detected and the CLK frequency drops again. Thus, it is possible to avoid the re-drop of the CLK frequency by gradually raising the CLK frequency from FL to F0 instead of rapidly increasing the CLK frequency.

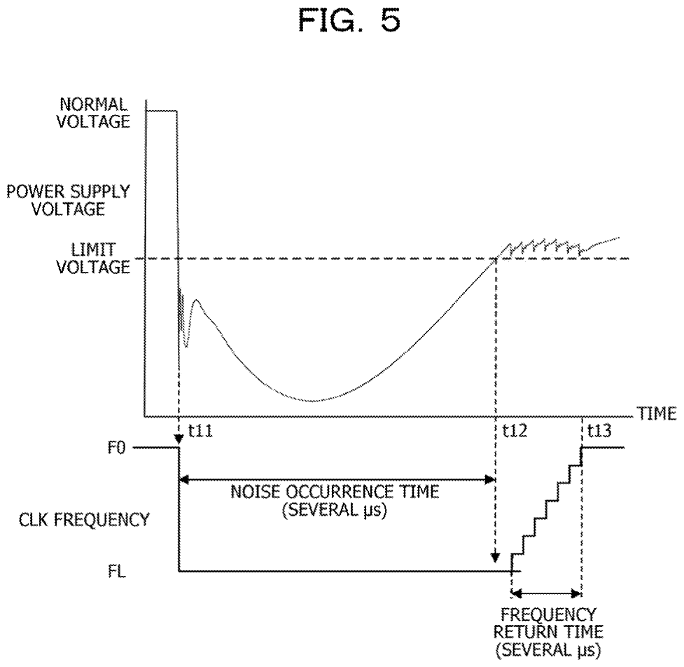

FIG. 5 is a timing chart illustrating an example of the clock control when the maximum power supply noise occurs in the processor of the comparative example. In the following, the maximum power supply noise may be referred to as the maximum noise.

At a start of operation, the power supply voltage is the normal voltage and the CLK frequency is F0. At time t11, the power supply noise occurs and the power supply voltage drops below the limit voltage, so that the CLK frequency is changed to FL.

Thereafter, after the power supply voltage further drops, the power supply voltage starts to rise due to reduction of the power supply noise, and at time t12, the power supply noise ends and the power supply voltage reaches the limit voltage. Thus, control is performed to gradually raise the CLK frequency, and at time t13, the CLK frequency returns to F0.

In this case, the noise occurrence time is several microseconds (μs) from the time t11 to the time t12, and a frequency return time, which is a time until the CLK frequency returns from FL to F0, is several μs from immediately after the time t12 to the time t13. The frequency return time is set to several μs in consideration of a voltage recovery time when the maximum noise occurs so that the CLK frequency does not drop again.

However, in a multi-core processor, the maximum noise occurs in a case where all cores start operating at the same time. In this case, long-period large noise occurs, but frequency of occurrence of the maximum noise is low because frequency of all the cores starting operation at the same time is low.

On the other hand, the power supply noise in a case where about several cores start operating at the same time is short-period small noise. In this case, the voltage recovery time is about several hundred nanoseconds (ns) or less, which is shorter than the voltage recovery time when the maximum noise occurs.

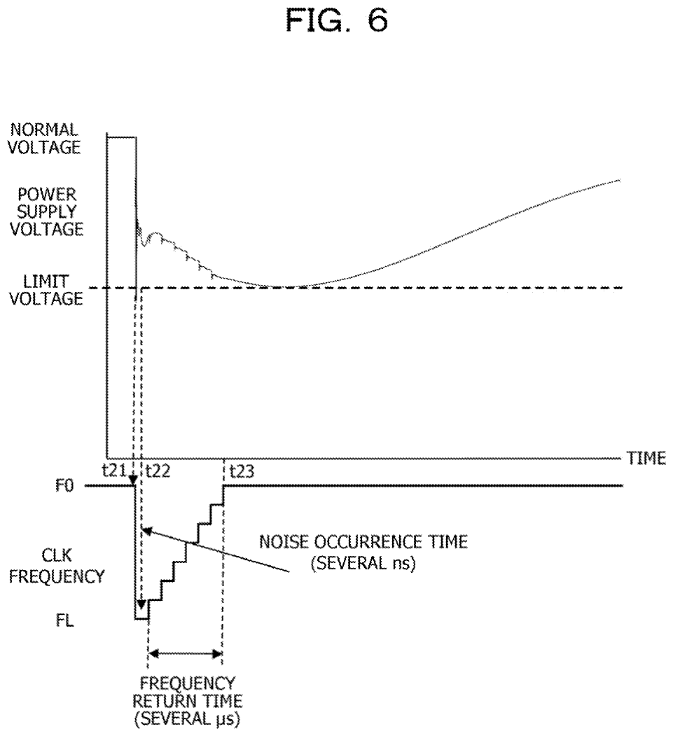

FIG. 6 is a timing chart illustrating an example of the clock control when short-period small noise occurs in the processor of the comparative example. At a start of operation, the power supply voltage is the normal voltage and the CLK frequency is F0. At time t21, the power supply noise occurs and the CLK frequency is changed to FL. Then, at time t22, the power supply noise ends and control is performed to gradually raise the CLK frequency, and at time t23, the CLK frequency returns to F0.

In this case, the noise occurrence time is several ns from the time t21 to the time t22, and the frequency return time is several μs from immediately after the time t22 to the time t23. Since the frequency return time is set on the basis of the voltage recovery time when the maximum noise occurs, it takes a long time for the CLK frequency to return from FL to F0 even in a case where the noise occurrence time is short.

When the short-period small noise occurs, the processor operates at the frequency lower than F0 for a long time, even though the power supply voltage recovers in a short time. Thus, performance of the processor is unnecessarily deteriorated.

In an electronic circuit of Japanese Laid-open Patent Publication No. 2017-17671, an oscillation frequency may be changed at high speed following the power supply noise, but the frequency return time is not optimized.

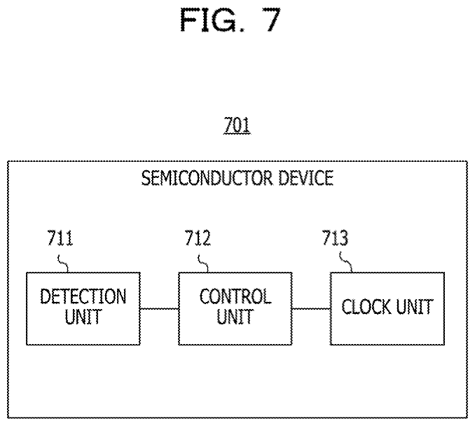

FIG. 7 illustrates a configuration example of a semiconductor device of the embodiment. A semiconductor device 701 of FIG. 7 includes a detection unit 711, a control unit 712, and a clock unit 713. The clock unit 713 outputs a clock signal.

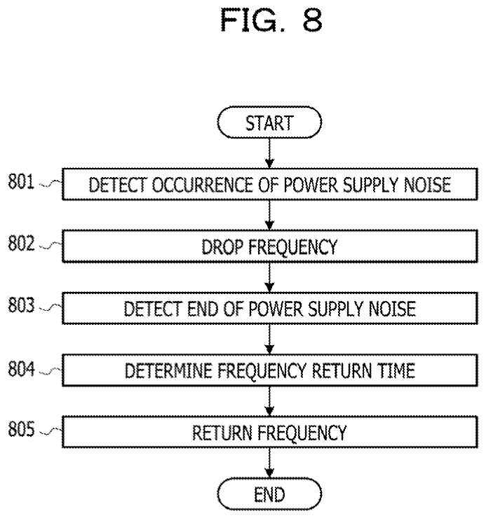

FIG. 8 is a flowchart illustrating an example of clock control performed by the semiconductor device 701 of FIG. 7. First, the detection unit 711 detects occurrence of power supply noise (Step 801), and the control unit 712 drops a frequency of a clock signal from a first frequency to a second frequency (Step 802).

Next, the detection unit 711 detects end of the power supply noise (Step 803), and the control unit 712 determines a frequency return time according to a noise occurrence time from the occurrence of the power supply noise to the end of the power supply noise (Step 804). Then, the control unit 712 returns the frequency of the clock signal from the second frequency to the first frequency on the basis of the frequency return time (Step 805).

According to the semiconductor device 701 of FIG. 7, a time for the semiconductor device 701 to operate at a low frequency may be shortened.

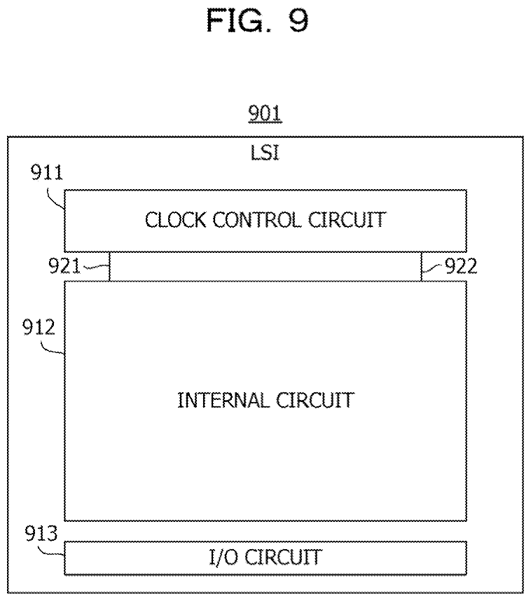

FIG. 9 illustrates a first hardware configuration example of LSI corresponding to the semiconductor device 701 of FIG. 7. LSI 901 of FIG. 9 includes a clock control circuit 911, an internal circuit 912, and an input/output (I/O) circuit 913. These components are hardware circuits. The LSI 901 may also be a processor.

The internal circuit 912 performs a logical operation. The I/O circuit 913 receives data to be used for the logical operation from the outside, outputs the received data to the internal circuit 912, and outputs an operation result output from the internal circuit 912 to the outside. The clock control circuit 911 generates a clock signal, and outputs the clock signal to the internal circuit 912 via a signal line 922. At this time, the clock control circuit 911 detects a power supply voltage of the internal circuit 912 via a signal line 921, and controls a frequency of the clock signal on the basis of the detected power supply voltage.

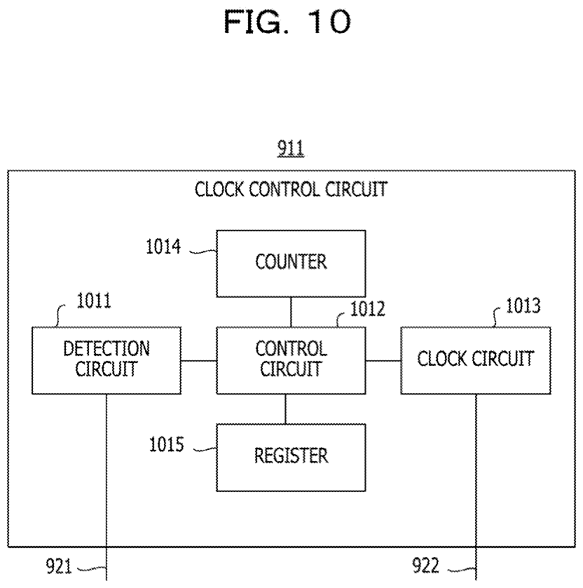

FIG. 10 illustrates a first hardware configuration example of the clock control circuit 911 of FIG. 9. The clock control circuit 911 of FIG. 10 includes a detection circuit 1011, a control circuit 1012, a clock circuit 1013, a counter 1014, and a register 1015.

The clock circuit 1013 may dynamically change a frequency of a clock signal. The clock circuit 1013 may also include a phase locked loop (PLL), a delay-locked loop (DLL), or a switch that switches the frequency of the clock signal.

The detection circuit 1011, the control circuit 1012, and the clock circuit 1013 correspond to the detection unit 711, the control unit 712, and the clock unit 713 of FIG. 7, respectively.

The register 1015 stores a candidate time table. The candidate time table includes candidate times associated with a plurality of time ranges. The candidate times associated with the time ranges are candidates for the frequency return time. The register 1015 is an example of a storage unit. When the power supply noise occurs, the counter 1014 counts the noise occurrence time and outputs a count value count.

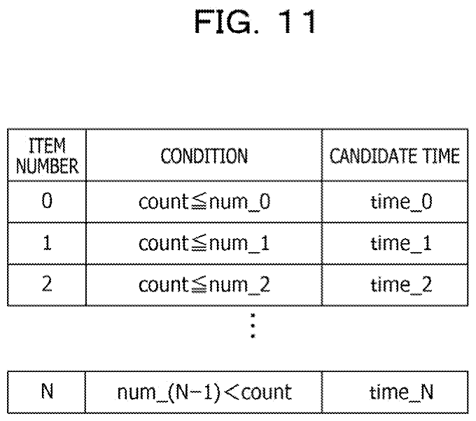

FIG. 11 illustrates an example of the candidate timetable. The candidate timetable of FIG. 11 includes N+1 entries (where N is an integer greater than or equal to 1), and each of the entries includes an item number, a condition, and a candidate time. The item number is identification information of the entry, and the condition is a determination condition for count representing the noise occurrence time.

num_i (i=0 to N) is a threshold for count, and time_i is the candidate time. time_i (i=1 to N) is longer than time_(i−1). The candidate time of each entry is associated with the condition of the entry.

For example, the condition of the 0th entry represents that count is less than or equal to num_0. The condition of the i-th (i=1 to N−1) entry represents that count is greater than num_(i−1) and less than or equal to num_i. The condition of the N-th entry represents that count is greater than num_(N−1).

The condition of each entry represents a time range to which count belongs, and the longer the noise occurrence time represented by count, the longer the candidate time corresponding to the time range to which count belongs.

The detection circuit 1011 detects the power supply voltage of the internal circuit 912 via the signal line 921, and detects the occurrence of power supply noise from the detected power supply voltage. Then, the detection circuit 1011 outputs a noise occurrence signal indicating the occurrence of the power supply noise to the control circuit 1012.

The control circuit 1012 controls the frequency of the clock signal by using a correlation between the noise occurrence time of the power supply noise and a period and magnitude of the power supply noise. When receiving the noise occurrence signal, the control circuit 1012 outputs, to the clock circuit 1013, a frequency drop signal indicating an instruction to change the frequency of the clock signal to the frequency FL at the time of a low-speed operation. Then, the control circuit 1012 starts measurement of the noise occurrence time by instructing the counter 1014 to start a count operation.

When receiving the frequency drop signal, the clock circuit 1013 changes the frequency of the clock signal to FL, and outputs the clock signal to the internal circuit 912 via the signal line 922. The counter 1014 starts counting the noise occurrence time.

Next, the detection circuit 1011 detects end of the power supply noise from the detected power supply voltage via the signal line 921. Then, the detection circuit 1011 outputs a noise end signal indicating the end of the power supply noise to the control circuit 1012.

When receiving the noise end signal, the control circuit 1012 instructs the counter 1014 to stop the count operation and acquires count from the counter 1014. Then, the control circuit 1012 uses the acquired count as the noise occurrence time to determine the frequency return time.

The control circuit 1012 accesses the candidate time table stored in the register 1015, and acquires the candidate time associated with the time range including the acquired count among the plurality of candidate times included in the candidate time table. As a result, it is possible to select the frequency return time according to the noise occurrence time.

Next, the control circuit 1012 uses the acquired candidate time as the frequency return time to start frequency return control. In the frequency return control, the control circuit 1012 controls the clock circuit 1013 so that the frequency of the clock signal gradually rises from FL to the frequency F0 of the normal operation during the frequency return time. F0 is an example of the first frequency and FL is an example of the second frequency.

The control circuit 1012 determines a time interval ΔT and a frequency increment ΔF so that a time when the frequency of the clock signal changes from FL to F0 matches the frequency return time and the frequency gradually rises from FL to F0. Then, the control circuit 1012 outputs a frequency rise signal indicating an instruction to raise the frequency by ΔF to the clock circuit 1013 at the interval ΔT.

Each time the clock circuit 1013 receives the frequency rise signal, the clock circuit 1013 raises the frequency of the clock signal by ΔF, and outputs the clock signal to the internal circuit 912 via the signal line 922. Then, when the frequency return time elapses, the frequency of the clock signal returns to F0. By gradually raising the frequency, it is possible to avoid a re-drop of the frequency due to the power supply noise occurred again.

The condition and the candidate time set in the candidate time table may be obtained by a prior simulation. However, when the condition and the candidate time are determined while evaluating the condition and the candidate time during operation of the LSI 901, accuracy of the condition and the candidate time is higher. Thus, it is desirable to be able to set the condition and the candidate time of the candidate time table from outside the clock control circuit 911.

Furthermore, since the number of periods of the power supply noise to be considered in the clock control is determined by the number and height of impedance peaks of a power supply system, it is desirable to determine the number of entries of the candidate timetable according to these values. The frequency return time may be further optimized by setting the condition and the candidate time of the candidate timetable so that the frequency return time corresponding to the number and height of the impedance peaks may be selected.

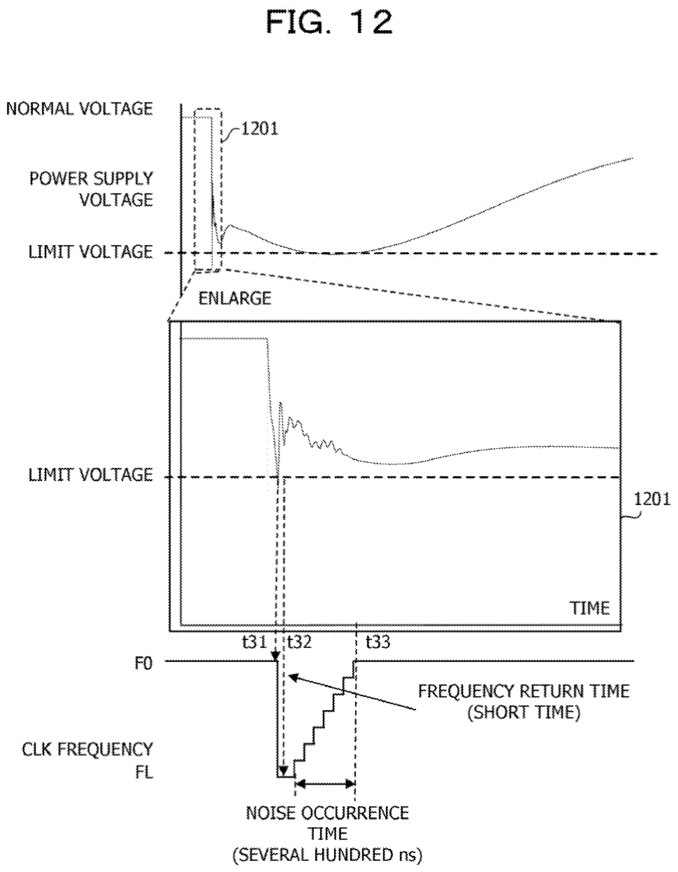

FIG. 12 is a timing chart illustrating an example of the clock control when short-period small noise occurs in the LSI 901 of FIG. 9. The CLK frequency represents the frequency of the clock signal output by the clock circuit 1013. An area 1201 of a graph indicating a change in the power supply voltage is illustrated in an enlarged manner below.

At a start of operation, the power supply voltage is the normal voltage and the CLK frequency is F0. At time t31, the power supply noise occurs and the CLK frequency is changed to FL. Then, at time t32, the power supply noise ends and control is performed to gradually raise the CLK frequency, and at time t33, the CLK frequency returns to F0.

In this case, the noise occurrence time is a short time from the time t31 to the time t32, and the frequency return time is several hundred ns from immediately after the time t32 to the time t33. Since the short frequency return time is selected according to the short noise occurrence time, the CLK frequency returns to F0 in a shorter time than in the clock control of FIG. 6.

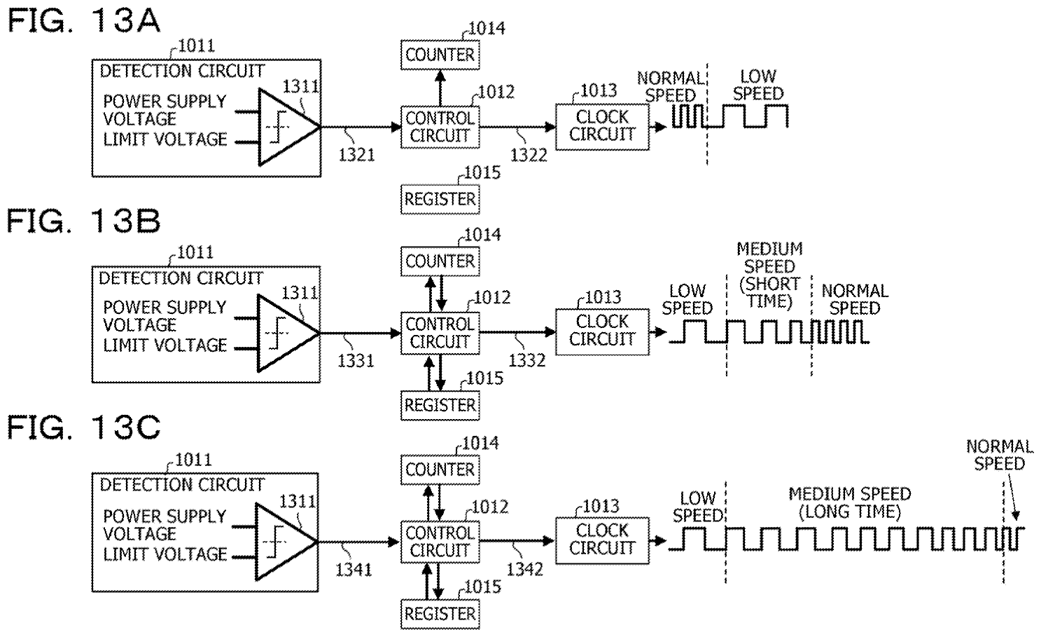

FIGS. 13A to 13C illustrate examples of first clock control performed by the clock control circuit 911 of FIG. 10. The detection circuit 1011 of FIGS. 13A to 13C includes a comparison circuit 1311.

FIG. 13A illustrates an example of control for changing the CLK frequency to FL when the power supply noise occurs. The comparison circuit 1311 compares the power supply voltage and a limit voltage of the internal circuit 912, and in a case where the power supply voltage drops below the limit voltage, outputs a noise occurrence signal 1321 indicating the occurrence of the power supply noise to the control circuit 1012.

When receiving the noise occurrence signal 1321, the control circuit 1012 outputs a frequency drop signal 1322 indicating an instruction to change the CLK frequency to FL to the clock circuit 1013, and instructs the counter 1014 to start a count operation. When receiving the frequency drop signal 1322, the clock circuit 1013 changes the CLK frequency to FL, and outputs the clock signal. As a result, the operation speed of the LSI 901 changes from the normal speed to the low speed.

FIG. 13B illustrates an example of control for gradually raising the CLK frequency when short-period small noise ends. The comparison circuit 1311 compares the power supply voltage and the limit voltage of the internal circuit 912, and in a case where the power supply voltage reaches the limit voltage, outputs a noise end signal 1331 indicating the end of the power supply noise to the control circuit 1012.

When receiving the noise end signal 1331, the control circuit 1012 instructs the counter 1014 to stop the count operation and acquires count indicating a short noise occurrence time from the counter 1014. Then, the control circuit 1012 acquires a short candidate time associated with a time range including the acquired count in the candidate timetable stored in the register 1015.

Next, the control circuit 1012 uses the acquired short candidate time as the frequency return time to determine ΔT and ΔF, and starts the frequency return control. In the frequency return control, the control circuit 1012 outputs a frequency rise signal 1332 indicating an instruction to raise the CLK frequency by ΔF to the clock circuit 1013 at the interval ΔT.

Each time the clock circuit 1013 receives the frequency rise signal 1332, the clock circuit 1013 raises the CLK frequency by ΔF, and outputs the clock signal to the internal circuit 912. As a result, the operation speed of the LSI 901 changes from the low speed to the medium speed, and the LSI 901 operates at the medium speed during the short frequency return time. When the frequency return time elapses, the CLK frequency returns to F0, and the operation speed of the LSI 901 changes from the medium speed to the normal speed.

FIG. 13C illustrates an example of control for gradually raising the CLK frequency when long-period large noise ends. The comparison circuit 1311 compares the power supply voltage and the limit voltage of the internal circuit 912, and in a case where the power supply voltage reaches the limit voltage, outputs a noise end signal 1341 indicating the end of the power supply noise to the control circuit 1012.

When receiving the noise end signal 1341, the control circuit 1012 instructs the counter 1014 to stop the count operation and acquires count indicating a long noise occurrence time from the counter 1014. Then, the control circuit 1012 acquires a long candidate time associated with a time range including the acquired count in the candidate timetable stored in the register 1015.

Next, the control circuit 1012 uses the acquired long candidate time as the frequency return time to determine ΔT and ΔF, and starts the frequency return control. In the frequency return control, the control circuit 1012 outputs a frequency rise signal 1342 indicating an instruction to raise the CLK frequency by ΔF to the clock circuit 1013 at the interval ΔT.

Each time the clock circuit 1013 receives the frequency rise signal 1332, the clock circuit 1013 raises the CLK frequency by ΔF, and outputs the clock signal to the internal circuit 912. As a result, the operation speed of the LSI 901 changes from the low speed to the medium speed, and the LSI 901 operates at the medium speed during the long frequency return time. When the frequency return time elapses, the CLK frequency returns to F0, and the operation speed of the LSI 901 changes from the medium speed to the normal speed.

According to the clock control circuit 911 of FIG. 10, the frequency return time may be selected from the plurality of candidate times according to the noise occurrence time from the occurrence to the end of the power supply noise. As a result, it becomes substantially possible to select an appropriate frequency return time according to a period and magnitude of the power supply noise, and it is possible to shorten a time for the LSI 901 to operate at the medium speed. By the reduction of the time to operate at the medium speed, a time to operate at the normal speed increases, and performance of the LSI 901 is improved.

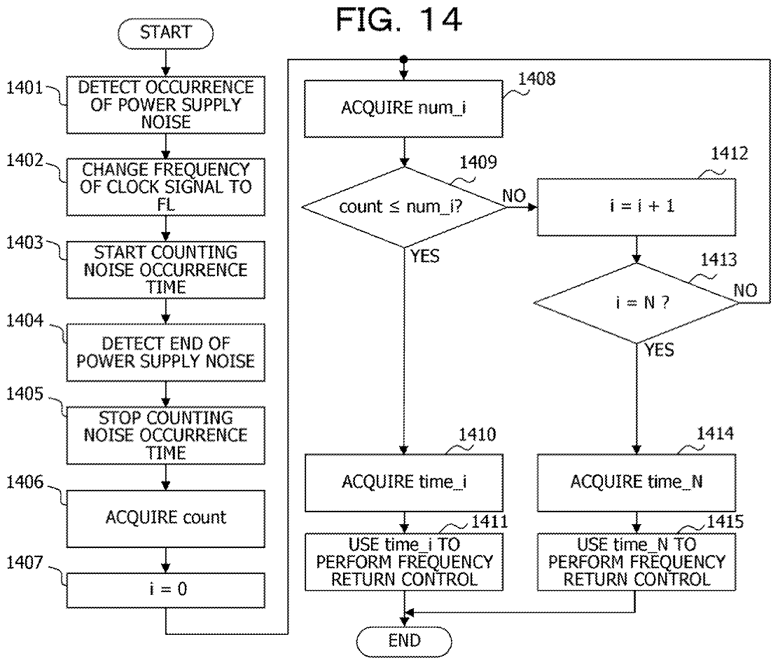

FIG. 14 illustrates a flowchart illustrating an example of the first clock control performed by the clock control circuit 911 of FIG. 10. First, the detection circuit 1011 detects occurrence of power supply noise from the power supply voltage of the internal circuit 912, and outputs a noise occurrence signal to the control circuit 1012 (Step 1401).

Next, the control circuit 1012 outputs a frequency drop signal to the clock circuit 1013 on the basis of the received noise occurrence signal, and the clock circuit 1013 changes a frequency of a clock signal to FL on the basis of the received frequency drop signal (Step 1402). Then, the control circuit 1012 instructs the counter 1014 to start a count operation, and the counter 1014 starts counting a noise occurrence time (Step 1403).

Next, the detection circuit 1011 detects end of the power supply noise from the power supply voltage of the internal circuit 912, and outputs a noise end signal to the control circuit 1012 (Step 1404).

Next, the control circuit 1012 instructs the counter 1014 to stop the count operation on the basis of the received noise end signal, and the counter 1014 stops counting the noise occurrence time (Step 1405). Then, the control circuit 1012 acquires count from the counter 1014 (Step 1406).

Next, the control circuit 1012 sets a control variable i indicating the entry of the candidate time table to 0 (Step 1407), and acquires num_i included in the condition from the i-th entry having the item number “i” (Step 1408). Then, the control circuit 1012 compares count acquired from the counter 1014 with num_i (Step 1409).

In a case where count is less than or equal to num_i (YES in Step 1409), the control circuit 1012 acquires time_i from the i-th entry (Step 1410), and uses time_i as the frequency return time to perform the frequency return control (Step 1411).

On the other hand, in a case where count is greater than num_i (NO in Step 1409), the control circuit 1012 increments i by 1 (Step 1412), and compares i and N (Step 1413). In a case where i is less than N (NO in Step 1413), the control circuit 1012 repeats the processing of Step 1408 and subsequent steps.

On the other hand, in a case where i reaches N (YES in Step 1413), the control circuit 1012 acquires time_N from the N-th entry (Step 1414), and uses time_N as the frequency return time to perform the frequency return control (Step 1415).

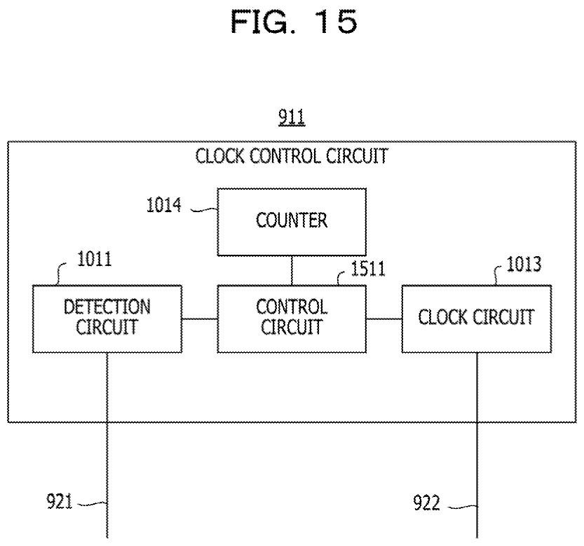

FIG. 15 illustrates a second hardware configuration example of the clock control circuit 911 of FIG. 9. The clock control circuit 911 of FIG. 15 has a configuration in which the register 1015 is deleted from the clock control circuit 911 of FIG. 10 and the control circuit 1012 is replaced with a control circuit 1511. The control circuit 1511 corresponds to the control unit 712 of FIG. 7.

The operation of the detection circuit 1011, the clock circuit 1013, and the counter 1014 is similar to that of the clock control circuit 911 of FIG. 10.

When receiving the noise occurrence signal from the detection circuit 1011, the control circuit 1511 outputs, to the clock circuit 1013, a frequency drop signal indicating an instruction to change the frequency of the clock signal to the frequency FL at the time of the low-speed operation. Then, the control circuit 1511 instructs the counter 1014 to start a count operation.

When receiving a noise end signal from the detection circuit 1011, the control circuit 1511 instructs the counter 1014 to stop the count operation and acquires count from the counter 1014. Then, the control circuit 1511 uses the acquired count as X to calculate a frequency return time TR by the following equation.

TR=aₙXⁿ+aₙ₋₁Xⁿ⁻¹+ . . . +a₁X¹+a₀ (1)

A right side of Equation (1) is an n-th order polynomial of X (n is an integer greater than or equal to 1), and TR increases as X increases.

Next, the control circuit 1511 uses the calculated TR as the frequency return time to perform the frequency return control to gradually raise the frequency of the clock signal from FL to F0.

Values of a coefficient aₙ to a coefficient a₁ and a constant term a₀ in Equation (1) may be obtained by a prior simulation. However, when the values of the coefficient aₙ to the coefficient a₁ and the constant term a₀ are determined while evaluating these values during the operation of the LSI 901, accuracy of these values is higher. Thus, it is desirable to be able to set the values of the coefficient aₙ to the coefficient a₁ and the constant term a₀ from outside the clock control circuit 911.

Furthermore, the frequency return time may be further optimized by setting the values of the coefficient aₙ to the coefficient a₁ and the constant term a₀ so that the frequency return time corresponding to the number and height of the impedance peaks of the power supply system may be calculated.

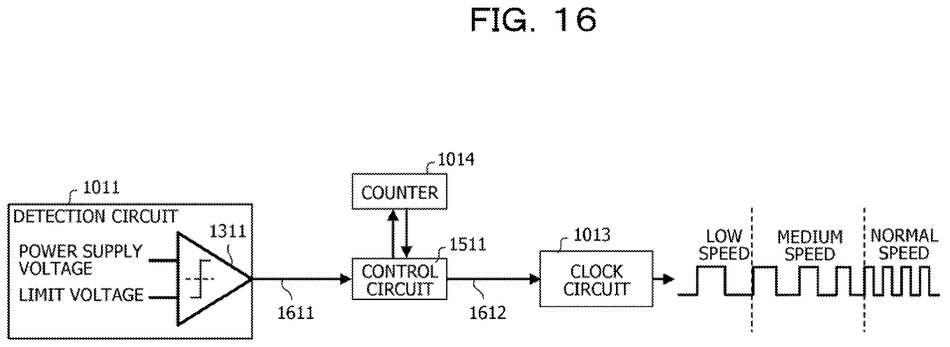

FIG. 16 illustrates an example of second clock control performed by the clock control circuit 911 of FIG. 15. The comparison circuit 1311 compares the power supply voltage and the limit voltage of the internal circuit 912, and in a case where the power supply voltage reaches the limit voltage, outputs a noise end signal 1611 indicating the end of the power supply noise to the control circuit 1511.

When receiving the noise end signal 1611, the control circuit 1511 instructs the counter 1014 to stop the count operation and acquires count indicating a noise occurrence time from the counter 1014. Then, the control circuit 1511 uses the acquired count as X to calculate TR by Equation (1).

Next, the control circuit 1511 uses the calculated TR as the frequency return time to determine ΔT and ΔF, and starts the frequency return control. In the frequency return control, the control circuit 1511 outputs a frequency rise signal 1612 indicating an instruction to raise the CLK frequency by ΔF to the clock circuit 1013 at the interval ΔT.

Each time the clock circuit 1013 receives the frequency rise signal 1612, the clock circuit 1013 raises the CLK frequency by ΔF, and outputs the clock signal to the internal circuit 912. As a result, the operation speed of the LSI 901 changes from the low speed to the medium speed, and the LSI 901 operates at the medium speed during the frequency return time. When the frequency return time elapses, the CLK frequency returns to F0, and the operation speed of the LSI 901 changes from the medium speed to the normal speed.

According to the clock control circuit 911 of FIG. 15, the frequency return time may be calculated according to the noise occurrence time from the occurrence to the end of the power supply noise. As a result, it becomes substantially possible to select an appropriate frequency return time according to a period and magnitude of the power supply noise, and it is possible to shorten a time for the LSI 901 to operate at the medium speed. By the reduction of the time to operate at the medium speed, a time to operate at the normal speed increases, and performance of the LSI 901 is improved.

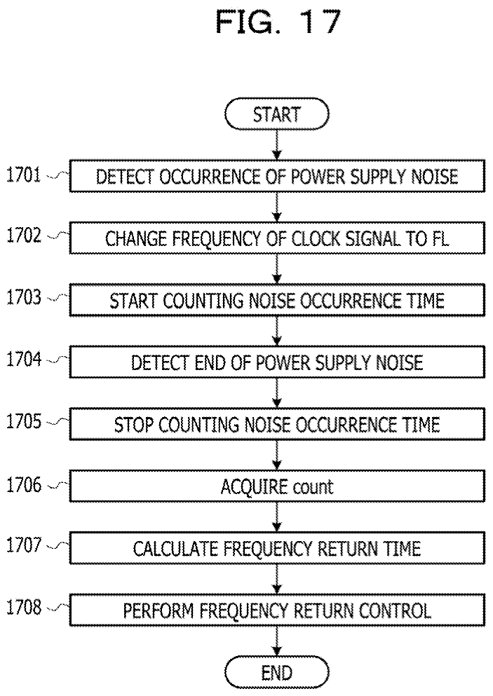

FIG. 17 illustrates a flowchart illustrating an example of the second clock control performed by the clock control circuit 911 of FIG. 15. Processing in Step 1701 to Step 1706 is similar to the processing in Step 1401 to Step 1406 of FIG. 14.

When count is acquired from the counter 1014, the control circuit 1511 uses the acquired count as X to calculate TR by Equation (1) (Step 1707). Then, the control circuit 1511 uses the calculated TR as the frequency return time to perform the frequency return control (Step 1708).

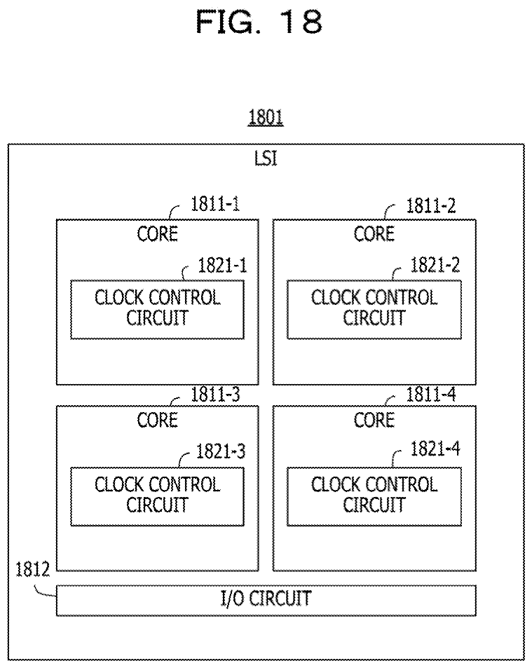

FIG. 18 illustrates a second hardware configuration example of the LSI corresponding to the semiconductor device 701 of FIG. 7. LSI 1801 of FIG. 18 is a multi-core processor, and includes a core 1811-1 to a core 1811-4 and an I/O circuit 1812. These components are hardware circuits. A core 1811-j (j=1 to 4) includes a clock control circuit 1821-j.

The core 1811-j performs operation processing. The I/O circuit 1812 receives data to be used for the operation processing from the outside, outputs the received data to the core 1811-j, and outputs an operation result output from the core 1811-j to the outside. The clock control circuit 1821-j generates a clock signal used by the core 1811-j. The clock control circuit 1821-j has, for example, a configuration similar to that of the clock control circuit 911 illustrated in FIG. 10 or FIG. 15, and performs similar clock control.

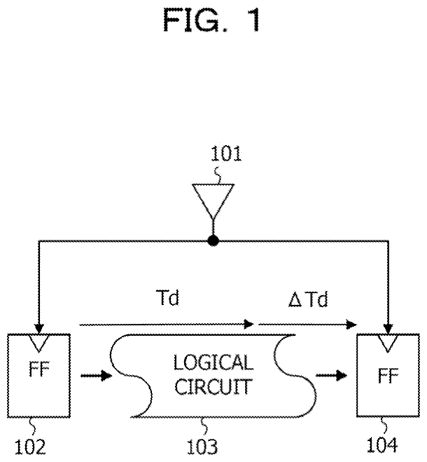

The configurations of the LSI of FIG. 1, the semiconductor device 701 of FIG. 7, the LSI 901 of FIG. 9, and the LSI 1801 of FIG. 18 are merely examples, and some components may also be omitted or changed according to use or conditions of the LSI or the semiconductor device. For example, the number of cores 1811-j included in the LSI 1801 of FIG. 18 may also be 1 to 3, or 5 or more. The configurations of the clock control circuit 911 of FIGS. 10 and 15 are merely examples, and some components may also be omitted or changed according to the configuration or conditions of the LSI.

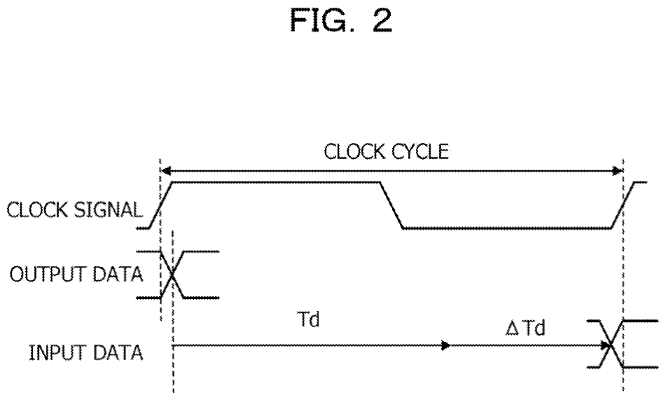

The clock signal and the data signal of FIG. 2 are merely examples, and the clock signal and the data signal change according to the LSI. The timing charts of FIGS. 3, 5, 6, and 12 are merely examples, and the timing chart of the clock control changes according to the LSI and the power supply noise. The clock control illustrated in FIGS. 4A and 4B, 13A to 13C, and 16 is merely an example, and the clock control changes according to the LSI and the power supply noise.

The flowcharts of FIGS. 8, 14, and 17 are merely examples, and some types of processing may also be omitted or changed according to the configuration or conditions of the LSI or the semiconductor device. The candidate timetable of FIG. 11 is merely an example, and other types of conditions and candidate times may also be used. Equation (1) is merely an example, and the control circuit 1511 may also use another calculation equation to calculate the frequency return time TR.

While the disclosed embodiment and the advantages thereof have been described in detail, those skilled in the art will be able to make various changes, additions, and omissions without departing from the scope of the embodiment as explicitly set forth in the claims.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that the various changes, substitutions, and alterations could be made hereto without departing from the spirit and scope of the invention.

What is claimed is:

1. A semiconductor device comprising:
a clock circuit that outputs a clock signal of a first frequency;
a detection circuit that detects occurrence of power supply noise and end of the power supply noise; and
a control circuit that drops, in a case where the occurrence of the power supply noise is detected, a frequency of the clock signal from the first frequency to a second frequency, determine a frequency return time according to a noise occurrence time from the occurrence of the power supply noise to the end of the power supply noise, and returns the frequency of the clock signal from the second frequency to the first frequency on the basis of the frequency return time.

2. The semiconductor device according to claim 1, wherein the control circuit controls the clock circuit such that the frequency of the clock signal gradually rises from the second frequency to the first frequency during the frequency return time.

3. The semiconductor device according to claim 1, further comprising
a memory that stores candidate times associated with a plurality of time ranges,
wherein the control circuit uses a candidate time, among the candidate times associated with the plurality of time ranges, associated with a time range that includes the noise occurrence time as the frequency return time to return the frequency of the clock signal from the second frequency to the first frequency.

4. The semiconductor device according to claim 1, wherein the control circuit uses the noise occurrence time to calculate the frequency return time, and uses the calculated frequency return time to return the frequency of the clock signal from the second frequency to the first frequency.

5. A clock control method comprising steps of:
detecting occurrence of power supply noise;
dropping a frequency of a clock signal from a first frequency to a second frequency;
detecting end of the power supply noise;
determining a frequency return time according to a noise occurrence time from the occurrence of the power supply noise to the end of the power supply noise; and
returning the frequency of the clock signal from the second frequency to the first frequency based on the frequency return time.

6. The clock control method according to claim 5, wherein in the returning the frequency of the clock signal, controlling the frequency of the clock signal to gradually rise from the second frequency to the first frequency during the frequency return time.

7. The clock control method according to claim 5, wherein in the returning the frequency of the clock signal, using a candidate time, among candidate times associated with a plurality of time ranges, associated with a time range that includes the noise occurrence time as the frequency return time to return the frequency of the clock signal from the second frequency to the first frequency.

8. The clock control method according to claim 5, wherein in the returning the frequency of the clock signal, using the noise occurrence time to calculate the frequency return time, and using the calculated frequency return time to return the frequency of the clock signal from the second frequency to the first frequency.
